(19) United States
(12) Patent Application Publication
(10) Pub. No.: US 2022/0019402 A1
(43) Pub. Date: Jan. 20, 2022

(54) SYSTEM TO CREATE MOTION ADAPTIVE AUDIO EXPERIENCES FOR A VEHICLE

(71) Applicant: Boris Salchow, Los Angeles, CA (US)

(72) Inventor: Boris Salchow, Los Angeles, CA (US)

(21) Appl. No.: 17/377,309

(22) Filed: Jul. 15, 2021

Related U.S. Application Data
(60) Provisional application No. 63/052,917, filed on Jul. 16, 2020.

(51) Int. Cl. G06F 3/16; G01S 19/52; G01P 15/18

(52) U.S. Cl. CPC G06F 3/165; G01P 15/18; G01S 19/52

(57) ABSTRACT

A system for creating motion adaptive audio experiences using available acceleration and speed data of a host device, such as a vehicle or a mobile phone in a vehicle, to determine acceleration and speed values, as well as to identify moments when the device has stopped moving making the speed zero. The system selects playback characteristics of digital audio files based on acceleration and speed of the device and orchestrates playback of the selected digital audio files through an existing audio system. As such, when the speed or acceleration of the vehicle changes, the audio play back to the user is also changed in order to provide an audio experience for users that is adaptive to vehicle motion.

### BACKGROUND

### Technical Field

The present disclosure generally relates to software and more particularly, to software for providing an adaptive audio experience based on movement characteristics of a vehicle.

### Description of the Related Art

Stereo systems are known, and have been for many years. Such stereo systems are commonly incorporated into vehicles and more recently, mobile electronic devices. Stereo systems are typically controlled by a user interface, which may include knobs, a touch screen panel, or other user input device to control audio playback, such as selection of a song as well as music characteristics such as volume, fade, balance, bass, treble, and others. More modern systems contain software that enables the selection of songs stored as digital files by a user through touch screen inputs. Some audio systems and software programs have been developed to enable music streaming from a remote service or from files on a remote electronic device, such as a mobile phone or tablet, to be played through a vehicle's audio system. However, such audio and software systems are limited in that they play back songs in exactly the form in which they were previously produced and recorded. The length, structure, arrangement, intensity or other characteristics of the composition cannot be altered.

### BRIEF SUMMARY

The present disclosure is generally directed to a system and method that creates an adaptive audio experience for users. The systems and methods described herein create an ongoing ‘soundtrack’ similar to a film soundtrack. This is a different content experience than listening to songs. The software uses available acceleration, speed and heading data of a host device, such as a vehicle or a mobile phone in a vehicle, to identify inflection point moments when the vehicle has changed its velocity or other movement related parameters (e.g., stop, start, acceleration, and deceleration conditions). Then, based on a set of rules that interpret the above mentioned inflection point moments, the software selects digital audio files and orchestrates playback of the selected digital audio files through an existing audio system. Combining those digital audio files will create the actual audio playback for the user. In other words, the actual audio playback to the user is a combination of the selected digital audio files based on acceleration, heading and speed data. As such, when the speed or acceleration of the vehicle changes, the audio play back to the user is also changed in order to provide an audio experience for users that is adaptive to the vehicle's motion.

In one or more implementations, a method of adaptive audio experience in a vehicle may be summarized as including: obtaining motion data of the vehicle, the motion data of the vehicle including vehicle acceleration data, vehicle speed data, or both; interpreting the motion data and orchestrating playback of digital audio files, wherein the orchestrated playback includes correlating playback characteristics of the digital audio files to at least one of: acceleration values of the vehicle, and speed values of the vehicle.

In another implementation, the interpreting of the motion data further includes identifying stop and start conditions of the vehicle. Additionally, the orchestrated playback further includes correlating playback characteristics of the digital audio file to stop and start conditions of the vehicle. In another implementation, the playback characteristics of the digital audio files includes tone, intensity, volume, bass, low pass filter, high pass filter and treble.

In other non-limiting features of some implementations, determining acceleration and speed values of the vehicle includes: averaging the vehicle speed and acceleration data to filter out short-term oscillation of the vehicle. In yet another implementation, determining acceleration and speed values of the vehicle includes: averaging vehicle GPS signals to smooth the GPS signals. In another implementation, determining acceleration and speed values of the vehicle includes: adaptive smoothing and averaging of vehicle acceleration and speed data based on absolute speed. In still another implementation, determining acceleration and speed values of the vehicle includes: distilling motion direction of the vehicle through a vector calculation by removing gravitational forces from the vector calculation.

In still other implementations, orchestrating the playback of digital audio files includes: allocating a plurality of first subsets of the plurality of digital audio files to each of a plurality of acceleration directions. In another implementation, the method may include that orchestrating playback of digital audio files includes: determining an instance of vehicle acceleration and a vehicle acceleration direction at the instance of vehicle acceleration. In still another implementation, the method may include that orchestrating playback of digital audio files includes: selecting, based on the vehicle acceleration direction, a playback characteristic of the digital audio file corresponding to the vehicle acceleration direction. In another implementation, the method may further comprise: selecting a second digital audio file based on vehicle speed. In yet another implementation, the method may further comprise: continuously adjusting a playback property of the second digital audio file based on vehicle speed. In another implementation, the method may further comprise: simultaneously orchestrating playback of a first digital audio file that is flexible in time of occurrence and an additional digital audio files with an independent time of occurrence.

### BRIEF DESCRIPTION OF THE SEVERAL VIEWS OF THE DRAWINGS

For a better understanding of the implementations, reference will now be made by way of example only to the accompanying drawings. In the drawings, identical reference numbers identify similar elements or acts. The sizes and relative positions of elements in the drawings are not necessarily drawn to scale. For example, the shapes of various elements and angles are not necessarily drawn to scale, and some of these elements may be enlarged and positioned to improve drawing legibility. Further, the particular shapes of the elements as drawn are not necessarily intended to convey any information regarding the actual shape of the particular elements, and may have been selected solely for ease of recognition in the drawings.

FIG. 1 is a flowchart illustrating one or more implementations of a method for providing a motion adaptive audio experience for a vehicle according to the present disclosure.

FIG. 2 is a graphical representation of allocation of a first subset of digital audio samples according to device acceleration and rotation in the method of FIG. 1.

FIG. 3 is a graphical representation of audio playback over time of a second subset of digital audio samples according to device speed in the method of FIG. 1.

FIG. 4 is a graphical representation of playback of multiple layers of music in the method of FIG. 1.

FIG. 5 is a graphical representation of orchestration of dynamic and cohesive audio playback based on a combination of digital audio files in the method of FIG. 1.

FIG. 6 is an illustration of one or more implementations of a user interface according to the present disclosure.

FIG. 7 is a logic diagram of one or more implementations of a method for orchestrating playback of one or more audio samples based on inflection point moments.

FIG. 8 is a logic diagram that shows functions and calculations in the motion and velocity determination process in one or more implementations of the motion adaptive audio experience system.

FIG. 9 is a logic diagram that shows functions and calculations in the motion and velocity determination process in one or more implementations of the motion adaptive audio experience system.

FIG. 10 is a logic diagram that shows functions and calculations in the motion and velocity determination process in one or more implementations of the motion adaptive audio experience system.

FIG. 11 is a logic diagram that shows functions and calculations in the motion and velocity determination process in one or more implementations of the motion adaptive audio experience system.

### DETAILED DESCRIPTION

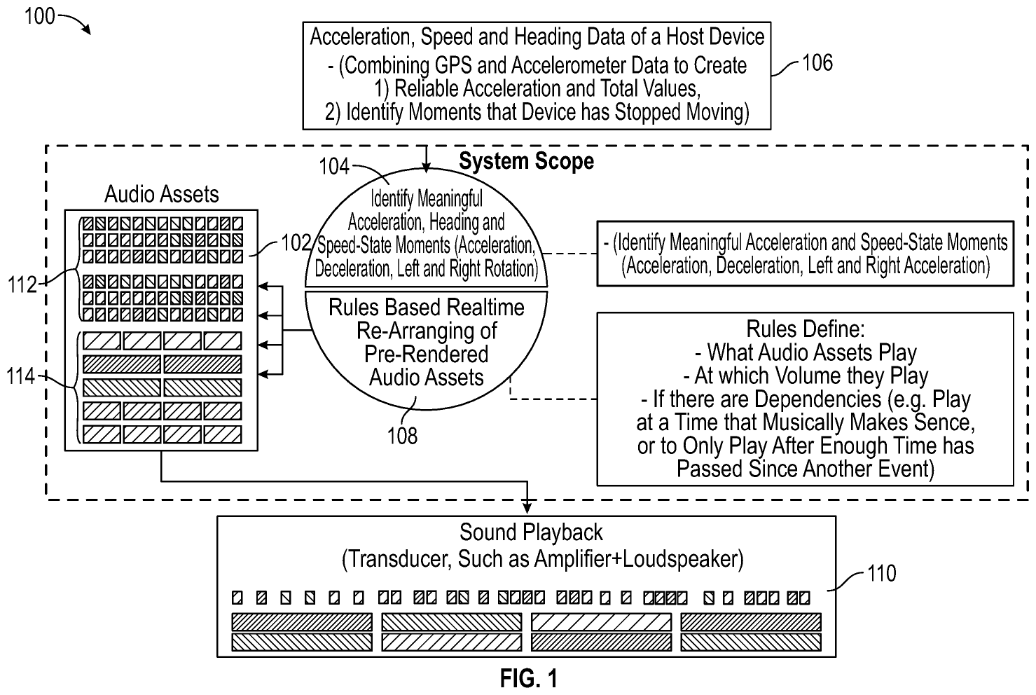

FIG. 1 is a flowchart or graphical representation that provides an overview of a system 100 for providing a motion adaptive audio experience for a vehicle. The system 100 continuously changes audio files selected for playback, and the playback characteristics of those audio files, such as the tone, intensity, volume, bass, treble, and other like characteristics, depending on the motion state of the device in which the system 100 is implemented. The following description will proceed by describing the system 100 implemented in a vehicle, such as a car, truck or SUV. However, it is to be understood that the system 100 is not limited to use only with automobiles. Rather, the software 100 can also be used with any other mobile device with audio playback capability, such as a boat, a motorcycle, a bicycle, an all-terrain vehicle, an off-road vehicle, a mobile electronic device, a smart phone, a tablet, or headphones, among other like devices, and such implementations and uses are included in the present disclosure.

The system 100 generally uses processor-executable instructions to create the motion adaptive audio experience based on a collection of digital audio files 102 that are provided to the system 100. In other words, the system 100 has access to and permission to use the digital audio files 102. The digital audio files 102 may be stored in any one of several different locations. For example, the digital audio files 102 may be stored locally on hardware of the vehicle. In other implementations, the digital audio files 102 are stored remotely on hardware in proximity to the vehicle, such as on a user's mobile device located in the vehicle, in which case, access to and transmission of the files can be provided to the system 100 through Bluetooth®, Wi-Fi®, Apple Car-Play®, and other like communication protocols. In one or more implementations, the digital audio files 102 are stored on remote servers, such as of the type owned by a streaming service wherein access to and transmission of the files can be provided via the above communication protocols. Further, the digital audio files 102 may include longer audio samples 114 (similar to the length of a typical song, or between about 0.5 and 6 minutes in length), with or without lyrics, and shorter audio samples 112 (such as a specific sound or short burst of a certain song), again without or without lyrics. In one or more implementations, the digital audio files 102 include both longer samples as well as shorter samples.

The first set of processor-executable instructions, indicated generally in FIG. 1 by reference 104, interprets existing motion data 106 of the vehicle. Such motion data 106 may include vehicle acceleration and speed data as the same is gathered by existing components of the vehicle, such as speedometers, accelerometers, GPS receivers, and other like devices. In one or more implementations, the motion data 106 is gathered by an electronic device external to the vehicle, such as by a user's mobile phone or tablet (e.g. through an accelerometer of the electronic device) and transmitted to the system 100. The first set of processor-executable instructions 104 use the motion data 106 to determine inflection point acceleration moments or motion states that should have an influence on the audio experience.

For example, the first set of processor-executable instructions 104 may determine left acceleration, right acceleration, and forwards and backwards acceleration, as well as deceleration in any of those directions, and combinations thereof. In one implementation, the motion data 106 of the vehicle may be used to determine that an inflection point motion change moment is occurring, because the vehicle is accelerating 5.2 feet per second squared forwards and 1.2 feet per second squared forwards to the left and both values are higher than thresholds that define when a significant acceleration is taking place. This information may also be described using the parameters North, South, East, and West, instead of (or in addition to) forward, backward, left, and right. In some implementations, the first set of processor-executable instructions 104 determines if the magnitude and direction of acceleration of the vehicle represent an inflection point moment. The same applies equally to a direction of the vehicle while traveling at relatively constant speeds (e.g. in between periods of acceleration), in one or more implementations.

Generally speaking, when the term acceleration is used herein, such as acceleration data or acceleration values, it will be understood that this includes negative acceleration (i.e., deceleration) and zero acceleration (i.e., constant velocity). Furthermore, generally speaking, when the term velocity is used herein, such as velocity data or velocity values, it will be understood that this includes negative velocity (i.e., backwards velocity) and zero velocity (i.e., stopped motion). The inflection point moments described herein can refer to pre-defined acceleration inflection point moments or velocity inflection point moments, or both. For example, if the acceleration of a vehicle in two directions, such as forward acceleration and reverse accelerator or deceleration, is charted on a line graph over time, periods of rapid acceleration or deceleration would appear as inflection points in the chart. The same is true for a chart of velocity of a vehicle over time.

The system 100 includes rules that identify these inflection point moments in the acceleration, heading and velocity of the vehicle. In other words, in one or more implementations, interpretation of the motion data 104 includes implementing rules that determine whether a certain change in acceleration or velocity represents an inflection point moment. In one non-limiting example, a rule may be implemented in system 100 that states that any detected change in acceleration in any direction at a specific point in time that is greater than “X” is an inflection point moment, where “X” is equal to 0.25 feet per second squared, 0.5 feet per second squared, 1.0 feet per second squared, 1.5 feet per second squared, 2.0 feet per second squared, or more or less. In a further non-limiting example, determination of the inflection point moment may be made with reference to a certain, pre-defined period of time rather than a specific time point. For example, any of the above change in acceleration values over “Y” time where “Y” is equal to 0.25 seconds, 0.5 seconds, 1.0 seconds, 1.25 seconds, 1.5 seconds, 2.0 seconds, or more or less. The methodology above can be applied to velocity in a similar manner. Of course, other rules and methods for determining inflection point moments, which may be more complex functions of acceleration and velocity over time, are contemplated herein with the above merely being a few non-limiting illustrative examples. As such, the system described herein identifies inflection point moments, which correspond to changes in acceleration, velocity, or heading, among other vehicle motion characteristics, and adapts the audio output to the user, as described in further detail below.

Further, the inflection point moments for both acceleration and velocity may be fixed and static (i.e., are a selected and adjustable value as described above) or they may be adaptive over time to account for differences in acceleration at different velocities. More specifically, the system 100 includes rules in the first set of processor-executable instructions 104 that account for the differences in acceleration at high speeds, where it is generally more difficult to reach an acceleration inflection point moment threshold than at lower speed, by changing the inflection point moment thresholds in response to the determined velocity. Such rules may be implemented in a number of different ways. In one non-limiting example, the system 100 includes selectable velocity thresholds that correspond to different acceleration inflection point moment thresholds. Thus, if the system 100 receives an input that the vehicle speed is below 50 kilometers per hour, the system 100 will reference the selected acceleration inflection point moment threshold for that velocity or velocity range (i.e., below 50 kilometers per hour), which may be 0.25 meters per second squared, 0.5 meters per second squared, 1 meters per second squared, 1.5 meters per second squared or more than 2 meters per second squared in some non-limiting and illustrative examples.

Similarly, if the system 100 receives an input that the vehicle velocity has exceeded the 50 kilometer per hour threshold, then the system 100 references the selected acceleration inflection point moment threshold for the corresponding vehicle velocity. Generally, the acceleration inflection point moment threshold will be selected to be lower at higher velocities than at lower velocities, but the same is not necessarily required. The system 100 may include any number of such velocity thresholds and corresponding selected acceleration inflection point moment thresholds, despite only one example being described above. In some non-limiting examples, the system 100 may include one, two, three, four, five, six, seven, eight, nine, ten or more different velocity thresholds (such as 10, 20, 30, 40, 50, 60, 70, 80, 90, or 100 or more kilometers per hour) with different corresponding acceleration inflection point moment thresholds in order to make the system 100 more responsive to differences in acceleration at different velocities.

In some other non-limiting examples, the first set of processor-executable instructions 104 include rules for adapting the acceleration inflection point moment thresholds over time by averaging velocity values over a selected time period to determine whether average velocity exceeds a certain selected threshold. Alternatively, the system 100 may determine a differential magnitude value for velocity as described below, and determine whether the differential magnitude value for velocity exceeds a threshold for a certain acceleration inflection point moment threshold, among other complex velocity and acceleration calculations that are contemplated herein. Such calculations may determine the speed or velocity of the vehicle for use in adapting the acceleration threshold point moments according to any of the methods or principles described herein.

In addition to speed adaptive thresholds of the type described above, the system 100 may also include rules, such as in the first set of processor-executable instructions 104, that change the inflection point moment thresholds for acceleration, rotation or velocity, or any used signal, depending on the actual occurring data magnitudes. This functionality accounts for different driving styles, or variances in data and data magnitudes that occur due to differences in driving styles, vehicle- or host device characteristics and may be referred to herein as driving style adaptive thresholds. In one non-limiting example, a more “aggressive driver” would be expected to experience higher accelerations and velocities over time compared to a more “passive driver” that does not accelerate as quickly or drive as fast. Thus, the system 100 stores or records acceleration and velocity values over time and references this history to adapt the acceleration inflection point moment thresholds. The system 100 may also perform a number of calculations or apply selected rules, such as of the type described herein, to the raw velocity and acceleration data before or after storage to more accurately represent the velocity or acceleration (or changes in velocity and acceleration) and use of the same for adapting the inflection point moment thresholds.

Once the system 100 stores and references the raw or processed velocity and acceleration data, the system 100 then determines whether an adjustment to the inflection point moment thresholds for velocity or acceleration, or both, is warranted. For example, if the velocity and acceleration history indicates that a particular driver consistently (i.e., at least 50% of the time) exceeds velocities of 50 kilometer per hour and accelerations of 1 meter per second squared, then the system 100 adapts the inflection point moment thresholds to be higher. In one non-limiting the example, the system 100 may adapt a base acceleration inflection point moment threshold from 0.5 meters per second squared to 0.75 meters per second squared based on the historical driving data for this driver. This process can be repeated for velocity inflection point moment thresholds according to selected velocity values. Similarly, the same process can be used to lower the inflection point moment thresholds for a more passive driver. In one non-limiting example where the historical velocity and acceleration data indicate that a driver does not consistently exceed 50 kilometers per hour and accelerations of 0.5 meters per second squared, the system 100 may adapt a base acceleration inflection point moment threshold of 0.5 meters per second squared to 0.25 meters per second squared. Thus, each type of driver will have an audio playback experience that adapts to their particular driving style based on the driving style adaptive thresholds in order to prevent constant musical reactions or a lack of musical reactions while driving.

Some aspects of the disclosure and of system 100 rely on a vehicle's or user's speed for certain functionality. While the speed of a vehicle may be determined based on hardware and software of a vehicle, such as a speedometer or GPS data in some non-limiting examples, the system 100 may also utilize the user's mobile device to determine the speed or velocity for different types of motion in some implementations. The different motion types can then be used to determine the inflection point moments and certain inflection point moment thresholds.

In one non-limiting example, the system 100 is implemented in a mobile device and determines the type of motion (i.e., walking, running, biking, or driving) to further customize the audio playback to the user based on the user's velocity or the movement type, or both. The system 100 determines the type of movement using various signals. The first signal, or “differential magnitude,” calculates differential values for each of a device's existing accelerometers in the X-, Y-, and Z-axis. The differential values demonstrate how much acceleration the mobile device is experiencing in each axis by calculating the absolute value (i.e., positive values) differences between acceleration in each axis over very short time windows, such as less than 0.25 seconds, less than 0.5 seconds, less than 1.0 seconds, 2.0 seconds, 3.0 seconds, or 4.0 or more seconds in some non-limiting examples. The above illustrative time windows also include all values between the stated values (i.e., the above ranges include 0.15 seconds as well as 2.75 seconds).

The three differential values for each axis are then combined to create one differential magnitude value. To determine the differential magnitude value, each of the differential values for the axis are squared and then the squared values are summed (i.e., X²+Y²+Z²). The differential magnitude value is the square root of the sum of the squared differential values in each axis (i.e., differential magnitude equals the square root of X²+Y²+Z² where X, Y, and Z are the differential values in each axis). There is a direct relationship between the differential magnitude value and how much the mobile device is moving, shaking, vibrating, or experiencing other motion (i.e., higher differential magnitude values correspond to higher amounts of movement or acceleration of the mobile device). The differential magnitude values (as well as potentially the individual differential magnitudes) would be higher when a user is walking with the mobile device (i.e., the mobile device is shaking or vibrating) as opposed to holding the mobile device embodying the system 100 while moving in a car or the mobile device resting on a surface while moving in a vehicle.

The second signal is a calculation of the speed of the mobile device based on Global Positioning System (“GPS”) data collected or calculated by GPS receivers, transceivers, and other like hardware of the mobile device. The second signal may include latency values that exceed selected thresholds for use of the second signal to directly feed the system 100 in some implementations. With improvements in GPS technology, however, the second signal may be used as a direct input to the system 100 for determining audio playback in the future. In some implementations, the second signal is used as a reference to check other values determined by the system 100, such as the differential magnitude or differential values above. In other words, the second signal is used to verify the accuracy of the other signals in some implementations.

The third signal is pedometer data based on a pedometer or other like hardware or software algorithm of the mobile device, which identifies if a user is walking or running and determines their steps or distance traveled as a result of movement of the mobile device.

The system 100 then determines the motion type (i.e, walking, biking, or moving in a vehicle) based on the above signals. More specifically, the system 100 determines a walking motion type by looking at all three signals, the differential magnitude values (first signal), the GPS data (the second signal), and the pedometer data (third signal). When the differential magnitude values are high, which suggests the mobile device is experiencing a high amount of movement, and the GPS speed data suggests walking values, such as less than 15 kilometers per hour or another like selected value, and the pedometer of the mobile device is activate and collecting data, the system 100 concludes that the user is walking. In a similar manner, the system 100 may also determine whether the user is running. For example, if the differential magnitude values are higher than are typical for walking, the GPS speed suggests a typical running speed such as between 15 kilometers per hour and 25 kilometers per hour, and the pedometer is active, then the system 100 can conclude the user is running.

The system 100 determines a bicycle or biking motion type using a similar process. For example, when the differential magnitude values are high, the GPS speed suggests a typical selected biking speed (i.e., higher than walking but lower than 35 kilometers per hour or another selected limit), and the pedometer of the mobile device is active, and each of these three conditions is true for a selected amount of time (i.e., less than 1 minute, 5 minutes, 10 minutes, 15 minutes, 20 minutes, 30 minutes or more in some non-limiting examples) than the system 100 concludes that the user is biking or the mobile device is experiencing a bicycle motion type.

By contrast, when the differential magnitude values are lower, which suggests the mobile device is relatively still, the GPS speed shows speeds of more than 20 kilometer per hour, or another selected threshold value, and the pedometer is not active, and all of these conditions are true for a selected time period, such as the time period described above, then the system 100 concludes that the motion type is a vehicle motion type. Once the system 100 determines the motion type, the system 100 calculates the mobile device's speed by looking at four different data sets from existing hardware and software of the mobile device, namely GPS data, accelerometer data, pedometer data, and compass data.

For walking motion types, the walking speed is determined based on the mobile device's pedometer and accelerometer data with the speed calculated by the system 100 being more accurate and having less latency relative to the mobile device's existing hardware and data. These improvements to the speed data are advantageous because they allow the system 100 to more accurately and effectively tailor the audio playback to the user's movement at a given instance in time (i.e., the audio playback more accurately reflects the user's movements in real time or near real time).

Simultaneously, or in a parallel manner, the system 100 checks the differential magnitude values described above. If an average of the differential magnitude values over a selected period of time surpasses 0.3, or another selected threshold, then system 100 assumes the walking speed to be 4 kilometers per hour, or another selected value. If the average of the differential magnitude does not pass the 0.3 threshold, then the system 100 assumes the walking speed is zero kilometers per hour. If the pedometer speed calculation above results in a higher speed value than the threshold 4 kilometers per hour per hour assumption, then the system 100 uses the speed calculation generated by the pedometer as the speed of the mobile device in the walking motion type. Otherwise, the system 100 will assume a speed value of 4 kilometers per hour or zero kilometers per hour, depending on the average differential magnitude values. Thus, the calculation of speed in the walking motion type accounts for higher walking speeds, where pedometer data generates a more accurate speed calculation as well as walking at lower speeds, in which case assumptions are made to provide a more consistent speed input to the system 100.

For the bicycle or biking motion type, the system 100 determines the speed of the mobile device using GPS speed data from the mobile device. Simultaneously or in parallel, the system 100 references the differential magnitude value. If an average of the differential magnitudes over a selected period surpasses 0.15 or another selected threshold, then the system 100 assumes a bicycling speed of 12 kilometers per hour. If the average does not exceed the threshold, the system 100 assumes the speed is zero kilometers per hour. As with the walking motion type, if the GPS speed results in a higher value than 12 kilometers per hour, then the system 100 uses the GPS speed as an input for the speed of the mobile device. Otherwise, the system assumes the speed is zero kilometers per hour.

For the vehicle motion type, calculation of the vehicle speed using the mobile device is a multi-part process. In a first step, the system 100 performs a calibration process when the vehicle is not in motion. More specifically, once the system 100 determines that the mobile device is in a vehicle, as described above, the system 100 will first attempt to identify instances in time where the vehicle is not in motion by combining differentials of each accelerometer to the differential magnitude value. The combination of the differentials may be the same process as above for the differential magnitude value, or may be calculated in a different manner in some implementations. If the differential magnitude value is under a specific threshold, then the system 100 assumes the vehicle is not in motion or is in a resting condition. The threshold differential magnitude value may be selected or may be adaptive based on the recent speed and acceleration history of the vehicle. In other words, the system 100 records the speed and acceleration data used to determine the differential magnitude value over time and stores a history of at least one, or all, of the speed, acceleration, and differential magnitude values over time, as further described below.

The system 100 then references the history to determine whether a change in the threshold magnitude value is warranted based on the change in the differential magnitude values over time. In one non-limiting example, if the vehicle is moving at constant speed and with relative minor acceleration over a period of time (i.e., driving on a highway at the speed limit), then the system 100 will reference the history of the differential magnitude values and may adapt the threshold value for determining that the vehicle is at rest based on this history. In such an example, the threshold value may be higher or lower than the initial threshold value at start-up of the system 100. The above process may be referred to herein as an initial calibration process for vehicle motion.

Once the system 100 determines that the vehicle is not in motion or is in a resting position through the initial calibration process, the system 100 generates calibrated accelerometer values by offsetting each accelerometer reading in each axis until the reading from the accelerometers is at zero or near zero (i.e., within 0.1 of zero), which may be referred to herein as gravity-offset calibration. The gravity-offset calibration eliminates gravitation from the system 100 which may otherwise pull at the accelerometers and distort the readings from the accelerometers. The two steps above, namely initial calibration and gravity-offset calibration may collectively be referred to herein as a calibration process in which the system 100 uses the differential magnitude history and an accelerometer offset to establish baseline values for future accelerations that affect audio playback, as described herein.

In a second step, the system 100 determines the mobile device's orientation within the vehicle in order to interpret the data collected from the mobile device regarding the direction of movement and acceleration or deceleration in different directions. After the calibration process, the system 100 waits for the first meaningful acceleration in a second step, which may be an acceleration in at least one axis that is above a selected threshold based on the readings from the accelerometer of the mobile device. In some implementations, the first meaningful acceleration after calibration will be assumed as a forward acceleration of the vehicle and will then be used to calculate the rotation of the mobile device's coordinate system and the vehicle's coordinate system to account for the orientation of the mobile device in the vehicle.

After the calculation of the rotation, the system is in “full sync” mode and the system 100 uses the mobile device's accelerometers in all three axis and mathematically rotates them in order to translate the sensed acceleration of the mobile device into acceleration of the vehicle (i.e., forward, reverse, left, right, up, or down acceleration of the vehicle). The system 100 then determines the vehicle's speed based on the detected or calculated amount of the vehicle's forward acceleration by integrating the forward acceleration value of the vehicle according to the basic principle that velocity or speed is equal to acceleration multiplied by time, or change in velocity over a change in time. Thus, the system 100 uses the detected or calculated acceleration of the vehicle to determine the speed of the vehicle in the vehicle motion type.

The vehicle speed determined by the above process may be misrepresented or inaccurate in some implementations due to misinterpretation of phone movements or the effect of gravitation on the accelerometers when the vehicle is moving uphill or downhill or is otherwise changing its position relative to a vertical axis. Thus, the system 100 uses the GPS speed data from the mobile device as a reference to check the accuracy of the calculated vehicle speed data and account for the effect of gravitation on the accelerometers. More specifically, the system 100 continuously changes the vehicle's calculated speed value based on acceleration to be closer to the current GPS speed determined by the mobile device while the vehicle is in a relatively constant state of motion as determine by a lack of acceleration or deceleration. During periods where the vehicle is braking or accelerating in an amount that exceeds a selected threshold, the system 100 bypasses the above process and does not change the calculated speed value based on acceleration to be closer to the current GPS speed to account for the latency with GPS speed relative to the calculated speed based on acceleration. Thus, the system 100 gives preference to the vehicle speed calculated via the vehicle's acceleration during periods of acceleration or deceleration above a selected threshold.

If a change in the input parameters cause the system 100 to no longer be in full sync mode, the system 100 can also calibrate while the vehicle is moving if the driving is consistent or homogenous enough for the system 100 to set the gravity-offset calibration described above. In other words, where the vehicle is moving at a relatively constant speed with minimal acceleration or braking (i.e., highway driving), the system 100 will detect acceleration values from the accelerometers of the mobile device that appear to be similar to when the vehicle is not moving or is at rest. The system 100 then performs the gravity-offset calibration and continues with the process described above, namely to wait until the first detected acceleration event. However, in this case, an assumption that the first acceleration is a forward acceleration is not applied because the first detected acceleration may be in any direction (i.e., forward, reverse, left, right, up, down). Rather, the system 100 references GPS data to check whether the first detected acceleration is acceleration or deceleration and in what direction. The system 100 then returns to full sync and continues to determine the vehicle's speed according to the above description.

The system 100 also includes a safety check algorithm to determine whether the vehicle speed calculated from acceleration is accurate or whether the system 100 is out of sync. Specifically, the system 100 determines whether the vehicle speed calculated based on acceleration develops similarly to the GPS speed over time. If so, then no further actions are needed and the system 100 continues with its operation. If, in one non-limiting example, the GPS speed is increasing while the calculated speed from acceleration is decreasing, then the system 100 bypasses the calculated speed process and relies on only the GPS speed until the mobile device detects the next point in time at which the vehicle is not in motion or is at rest. Then, the system 100 starts the process above over again with calibration and ongoing calculation of vehicle speed. Thus, the safety-check algorithm accounts for errors in GPS speed or a misinterpretation of data, such as interpreting a curve as an acceleration, among other examples.

In some implementations, the system 100 also accounts for movement of the mobile device in the vehicle by the user grasping and moving the device (which may be referred to as a “hand movement”) and avoids interpretation of these hand movements as vehicle accelerations. The system 100 accounts for hand movements by referencing the mobile device's rotation speed around the X-, Y-, and Z-axis. If those rotations, or in some implementations the averaged values of the rotations, all surpass a selected threshold rotation value, then the system 100 assumes that a hand movement has occurred. When a hand movement occurs, the system 100 stops referencing the accelerometers to determine the vehicle speed and instead only uses GPS speed. The system 100 then remains in the GPS only state until the next point in time at which the system 100 detects that the vehicle is no longer in motion or is at rest and the system 100 then restarts the calibration process above to return to full sync. Once in full sync, the system 100 can calculate the vehicle speed based on acceleration.

The system 100 also accounts for the period of time before the motion type is determined, in some implementations. This state of the system 100 may also be referred to herein as an “unknown state” mode. In the unknown state mode, the system 100 uses a combination of GPS and accelerometer data to create an approximation of the mobile device until the mobile device detects a motion type. Once a motion type is detected, the system 100 then determines the speed for that motion type as described above.

While the system 100 may utilize the raw speed data (i.e., the speed in kilometers per hour, miles per hour or another standard unit) to implement audio playback, the system 100 converts the raw speed data to a normalized value in some implementations for further processing by the system 100. More specifically, for each motion type described herein, the system 100 may assume a bracket of speed during which musical differences can occur. In other words, the system 100 has a selected range of speed that corresponds to audio playback or changes in audio playback in each motion type. The top end of the assumed speed range or bracket is a top speed that can be reached in each motion type. In one non-limiting the top speed for the walking motion type is assumed to be 15 kilometers per hour, the top speed for the bicycling or biking motion type is assumed to be 30 kilometers per hour, and the top speed for the vehicle motion type is assumed to be 150 kilometers per hour. Of course, these values can be selected according to design factors for the system 100 and may be any value between zero kilometers per hour and 300 kilometers per hour or more, in some implementations.

Once the top speed for each motion type is selected, the system 100 directly translates the raw speed in kilometers per hour over the selected range or bracket of speed values to a value from zero to 1. In more detail, the system 100 determines the normalized speed with a proportion that compares the calculated or determined raw speed with the selected top speed for each motion type (i.e., normalized speed for each motion type is equal to raw speed divided by selected top speed for that motion type). In some non-limiting examples, if a vehicle is moving at 150 kilometers per hour, the system 100 determines that the normalized speed value is equal to 1 because the raw speed is equal to the assumed or selected maximum speed for the vehicle motion type. Similarly, if the vehicle is moving at 75 kilometers per hour, the normalized speed value would be equal to 0.5. The same principle is applied to the other motion types to normalize the determined speed values for further processing in the system 100.

Thus, in some implementations, the above determinations or calculations of raw speed for each motion type are determined for the purpose of producing a normalized value corresponding to the speed that is then input to the auditory processing and playback components of the system 100. The audio processing and playback aspects of the system 100 therefore do not necessarily receive information regarding the motion type, but rather, determine the audio playback characteristics based on normalized speed and other factors discussed herein. In some implementations, the audio processing and playback functionality of the system 100 accounts for the motion type and varies the audio playback based on the determined motion type. Even if the audio playback does not necessarily depend on the motion type in all implementations, the use of different motion types and corresponding calculations is beneficial because they account for the different movement characteristics of the mobile device in each motion type and thus produce more accurate normalized speed values that are more responsive to the actual movement characteristics of the user during each type of motion. Thus, the use of different motion types improves the accuracy and responsiveness of the audio processing and playback functionality of the system 100.

The system 100 then uses a second set of processor-executable instructions, indicated generally in FIG. 1 by reference 108, to orchestrate the playback of one or more of the digital audio files 102 through an existing audio system 110. The existing audio system 110 may include a transducer, an amplifier, a loudspeaker, and other like devices for receiving the selected digital audio file(s) 102 and playing them back to the user through the speaker. The second set of processor-executable instructions 108 orchestrate the playback of the audio files 102 to construct a continuously changing listening experience. For example, the second set of processor-executable instructions 108 may define when audio files 102 play, at which volume the audio files 102 play, and if there are any dependencies to consider in the playback, such as whether to play the audio files 102 at a time that musically makes sense, or to only play after enough time has passed since another playback event. In one non-limiting example, the second set of processor-executable instructions 108 select one of the longer audio files 114 for continuous playback and one or more of the shorter audio samples 112 to be played over, and in combination with, the longer audio files 114, as described further herein, to create a musical soundtrack similar to a movie soundtrack, with continuous sound playback that changes based on determined inflection point moments.

In one or more implementations, the system 100 receives and processes only one direction of vehicle motion data, such as forward acceleration and deceleration and speed data, with the first set of processor-executable instructions 104 in order to define inflection point motion changes or motion states and to orchestrate playback via the second set of processor-executable instructions 108. Depending on the frequency of measuring, the first set of processor-executable instructions 104 can also include algorithms or processor-executable instructions for calculating acceleration from speed data by determining the change of velocity or speed over pre-defined time intervals. In one or more implementations, the system 100 receives the above data as well as left and right acceleration and deceleration or rotation data such that the system 100 can react to cross-acceleration. In yet further implementations, additional data, such as user input, information about geographical surroundings, such as through GPS positioning, or other automobile related parameters could be used to influence determination of inflection point moments in 104 as well and through that the playback orchestration in 108.

With respect to some non-limiting features of certain implementations, the motion data 106 is received and processed by the system 100 in order to make the motion data 106 more useful and reliable for the system 100. Specifically, the first set of processor-executable instructions 104 include an averaging algorithm to filter out short-term oscillation that could inadvertently change the audio output by the second set of processor-executable instructions 108. Such short-term oscillations may be caused by bumping of the car (such as speed bump or a person moving a smart phone that is used to gather motion data), for example. Further, the first set of processor-executable instructions 104 may include an averaging algorithm to smoothen GPS signals where GPS signals are used to gather motion data or to provide inputs regarding geographic position of the vehicle or landmarks near the vehicle and incorporate such information into the process of determining inflection point moments. The first set of processor-executable instructions 104 also includes adaptive smoothing and averaging (such as through an algorithm) based on absolute speed, as well as adaptive changing of thresholds for inflection point moment based on absolute speed. In other words, because higher acceleration values can be achieved at low speed than at comparatively higher speeds, the first set of processor-executable instructions 104 include averaging and smoothing algorithms that depend on absolute speed to provide more reliable decision making when determining inflection point acceleration moments. The first set of processor-executable instructions 104 may also include any other set of rules of instructions for processing the motion data 106 described herein.

Again, with respect to some non-limiting features of certain implementations, the first set of processor-executable instructions 104 includes a vector calculation to distill the relevant forward, back, and cross (e.g. left to right) acceleration. Such vector calculation provides the direction by removing gravitational forces from the equation. In one or more implementations, one or more of the above processor-executable instructions may not be necessary based on the quality of motion data 106 input to the first set of processor-executable instructions 104 and the system 100.

In another implementation, a first vector calculation is included that determines the direction of a host device inside a moving vehicle, to determine the relative rotation of the host device to the moving device. Then, once the relative rotation is known, a second vector calculation can be used to distill the relevant forward, back and cross acceleration, as well as heading changes.

The algorithms referenced above in the first set of processor-executable instructions 104 may average vehicle motion data over a set period of time. The set period of time is configurable such that the system 100 can interpret a variety of different types of motion data 106. For example, the motion data 106 may be available to the system 100 according to collection intervals established in the device. Each device may have different collection intervals. As such, the algorithms may average the motion data 106 at different intervals in different applications. Moreover, the “averages” may include a configurable number of data points included in the average. The system 100 can therefore be customized according to the motion data 106 input to the system 100.

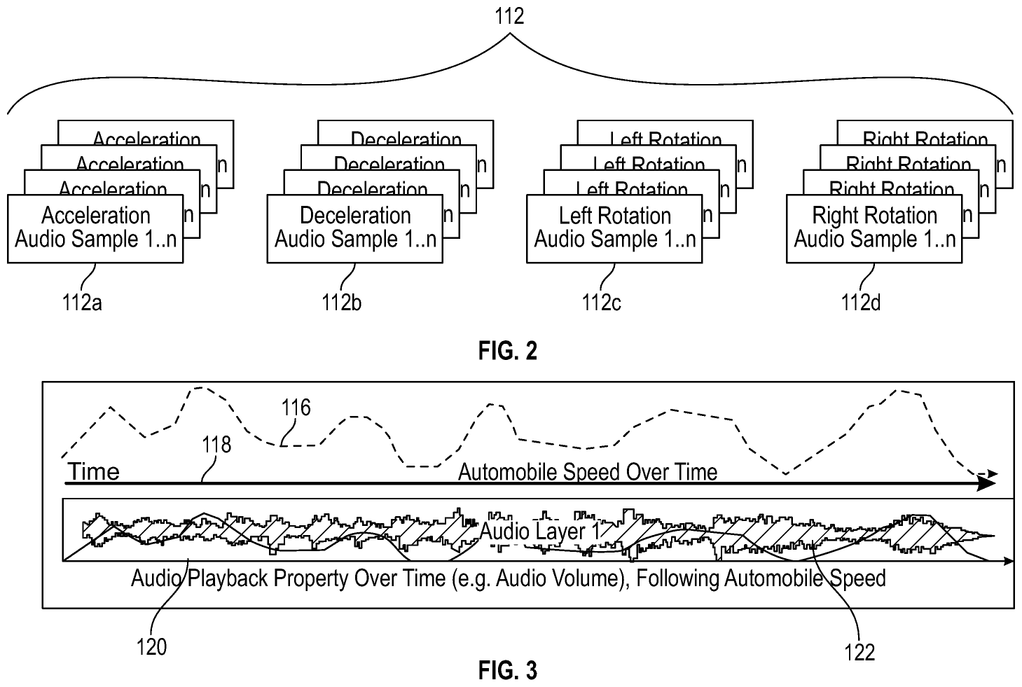

FIGS. 2-5 provide additional details regarding the orchestration of audio playback by the second set of processor-executable instructions 108, and particularly, orchestrating playback to account for vehicle acceleration and speed. More specifically, FIGS. 2-5 provide representations of how the system 100 simultaneously uses two different concepts to intelligently orchestrate playback of the digital audio files 102 based on motion data 106 to create a smooth sounding experience.

The first inflection point related modification to the playback of the first subset 112 or subset of shorter audio files 112 of the audio files 102 is triggered by acceleration, as shown in FIG. 2. The first subset 112 of the audio files 102 are shorter samples. There is no required length for the first subset 112 of audio files 102. For example, the samples in the first subset 112 could be one second or less in length, or could be up to 30 seconds or more in length. The first subset 112 of audio files 102 may also be called “one shots” or “stingers” and once triggered, the second set of processor-executable instructions 108 play a selected one or more of the first subset 112 of audio files 102 until their ending. In one or more implementations, the selected one or more of the first subset 112 of audio files 102 play until their ending without additional behavior or changes in playback characteristics. In some implementations, playback of the selected one or more of the first subset 112 of audio files 102 includes changing additional behavior or characteristics after playback begins, such as volume, for example.

In one or more implementations, the system 100 distinguishes between four different acceleration directions: forward acceleration, forward deceleration (or backward acceleration), as well as left and right acceleration. In one or more implementations, the system 100 distinguishes between more or less than four acceleration directions. In one or more implementations, the system 100 distinguishes between two or more acceleration directions as well as direction (heading) changes. The system 100 allocates one or more audio samples to each of these acceleration directions. In other words, the system 100 allocates the first subset 112 of audio files 102 to the acceleration directions by assigning one or more of the first subset 112 of audio files 102 to each direction. As such, the first subset 112 of the audio files 102 includes a first group of samples 112a allocated to acceleration (which may also be referred to herein as acceleration samples 112a), a second group 112b allocated to deceleration (which may also be referred to herein as deceleration samples 112b), a third group 112c allocated to left rotation when the heading changes to the left (which may also be referred to herein as left rotation samples 112c), and a fourth group 112d allocated to right rotation when the heading changes to the right (which may also be referred to herein as right rotation samples 112d). Each of the groups 112a, 112b, 112c, 112d includes one or more audio samples.

The system 100 is configured to select audio samples from the groups 112a, 112b, 112c, or 112d either randomly or sequentially. In one or more implementations, the system 100 is configured to control whether audio samples are selected randomly or sequentially from each group 112a, 112b, 112c, 112d. For example, the system 100 may be configured to always select randomly or sequentially, or may be configured to change between random or sequential selection based on the motion data 106 of the vehicle.

When the first set of processor-executable instructions 104 identifies or determines that an inflection point acceleration event is occurring (such as an acceleration event in one of the directions above), the second set of processor-executable instructions 108 determines if playback can be initiated immediately or playback can be delayed to fit a user-defined musical tempo grid and musical signature in order to create rhythmically cohesive and therefore musical audio experiences. In other words, the system 100 is configured to determine whether immediate playback or playback according to user-defined characteristics aligns with an overall rhythmically cohesive output and selects immediate or delayed feedback accordingly of one or more audio samples from a corresponding acceleration direction group 112a, 112b, 112c, 112d accordingly in order to maintain a rhythmically cohesive output.

Acceleration averages are calculated to determine acceleration events, as noted above. The time window and threshold values can be selected depending on the creative approach of an experience, either by a user or by the system 100. The selected time window to calculate the average as well as the threshold values also depend on the current absolute speed, as well as recent maximum acceleration peaks, in one or more implementations. After playback of an acceleration audio sample from one of the groups 112a, 112b, 112c, 112d, the next playback is delayed until a defined time passes, in one or more implementations. In some implementations, there is no delay between playback of acceleration samples from the groups 112a, 112b, 112c, 112d.

The first set of processor-executable instructions 104 and the second set of processor-executable instructions 108 allow for configuration of a number of different values or system 100. For example, in one or more implementations, configurable values include: Number of (acceleration/deceleration/left/right) stingers; maximum stinger thresholds (acceleration/deceleration/left/right); minimum stinger thresholds (acceleration/deceleration/left/right); time window to calculate acceleration averages (acceleration/deceleration, left/right); factor how higher speed increases time windows (acceleration/deceleration only); factor how higher speed decreases acceleration thresholds (acceleration/deceleration only); factor defining how strong a reached acceleration increases thresholds toward the maximum stinger thresholds; decay value that determines how fast or slow a threshold diminishes towards the minimum stinger thresholds; and time-grid, musical tempo and musical signature that playback triggers are synchronized to, if selected by the user.

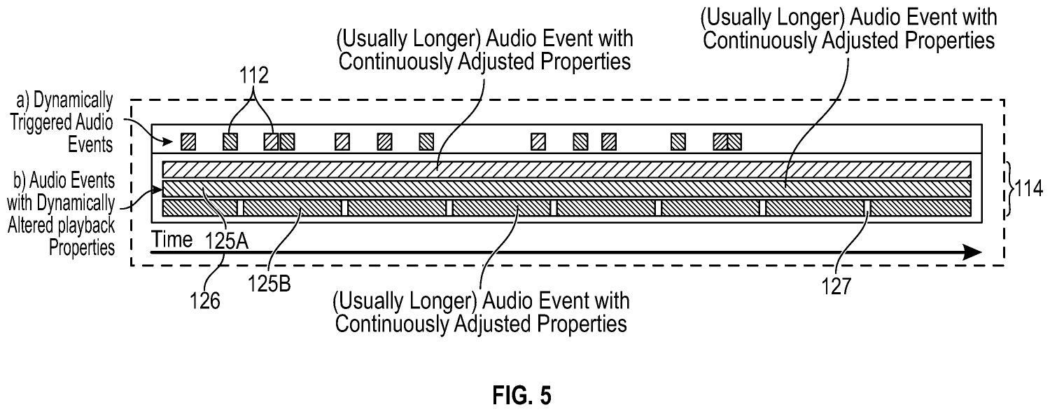

The second inflection point related modification to the second set of processor-executable instructions 108 is to play audio samples, which are triggered independent of acceleration events, but that instead have playback properties, such as playback volume, intensity, tempo, tone, treble, and base, that are continuously adjusted to speed, such as vehicle speed. In other words, the system 100 selects playback of one more of a second subset 114 of the audio files 102 (see FIG. 5) independent of acceleration events. The system 100 dynamically adjusts, based on vehicle speed, one or more playback characteristics of the selected one or more of the second subset of audio files 102. In one or more implementations, the second subset 114 of audio files 102 are longer audio samples relative to the first subset 112 of audio files 102.

Processor-executable instructions and formulas with configurable variables determine how properties relate to speed data. Further examples for playback properties that can be adjusted based on vehicle speed are playback volume, frequency filters, positioning in the cabin of a vehicle or any parameters that the software framework can offer. FIG. 3 illustrates how the speed of a vehicle or device can be applied continuously to volume of an audio sample. In FIG. 3, line 116 represents automobile speed over time (indicated by line 118). The vehicle speed 116 is correlated by the software 100 and the second set of processor-executable instructions 108 to an audio layer 120, with the playback volume (indicated by line 122) of the audio layer 120 adjusted based on speed 116. The audio layer 120 may include only audio files from the second subset 114 of the audio files 102, or may include a combination of audio files from the first and second subsets 112, 114 of the audio files 102. The vehicle speed 116 indicated in FIG. 3 is the vehicle speed as determined by the vehicle or device and included as part of the motion data 106. The first set of processor-executable instructions 104 average the speed values in the motion data 106 to produce an average speed line that mirrors the volume line 122. Otherwise stated, the line 122 output by the second set of processor-executable instructions 108 matches the average speed values as determined by the first set of processor-executable instructions 106, in one or more implementations. How the volume of an Audio layer follows the speed of a car is determined by a lookup table or formular and is often not running proportionally to the vehicles speed, as many Audio layers might fade out as higher speeds or fade in at lower speeds. As shown in FIG. 3, the line 122 has less jagged transitions than line 116, which represents the use of averages to prevent sharp spikes in volume or other playback characteristics.

Further, the system 100 has a reaction time for changing the playback properties of one or more music layers 120 based on a detected change in speed or acceleration. The reaction time can be selected and be fixed and static or can be adaptable based on the selected type of music experience as well as for each motion type described above. Using the motion types as a non-limiting example, the system 100 can specify how fast the music layer 120 (or any one of a number of different layers such as the first and second subsets 112, 114 of the audio files or additional layers 120) changes volume or other playback properties in response to a change in velocity or speed. When the user is in the walking motion type, the user may transition from jogging or running to standing within a second or half of a second. Without an adaptable reaction time, the system 100 views this change in velocity similarly to a vehicle braking from 150 kilometers per hour to zero kilometers per hour over the same period of time (i.e., one second or a half second). In the walking motion type, these types of start and stop motions that include rapid acceleration or deceleration can happen quite frequently, which may cause the system 100 to frequently change the playback properties in a corresponding manner. Using the volume as one illustrative and non-limiting example, the frequent and rapid change in motion while walking would produce repeated instances of changes in volume from max volume to zero volume.

To create a more enjoyable and accurate musical experience based on the motion type, the system 100 includes a maximum playback property change for each motion type defined as a maximum change rate in the playback property per second. The maximum change rate for each motion type may also be the same for acceleration or deceleration or may be different for acceleration and deceleration. For example, in the walking motion type, the maximum change rate per second may be 0.5 for acceleration and 0.05 for deceleration. In some implementations, the maximum change rate for deceleration in the walking motion type is the same as for acceleration, namely 0.5. For the bicycling motion type, the maximum change rate per second may be 0.05 for acceleration and 0.05 for deceleration. For the vehicle motion type, the maximum change rate per second may be 0.2 for acceleration and also 0.2 for deceleration. The above values are selected based on design factors for the system 100 and thus may change with further refinement or additional experimentation.

In addition, each music layer 120 may be configured individually and separately to have a maximum playback property change per second that is different from the above change per second for each motion type and the other layers. In some implementations, configuration of each music layer 120 also includes different maximum change rate per second for the different playback properties. In one non-limiting example, the volume change per second may have a different value than the treble or base change per second for a given music layer 120, which are both different from the maximum change per second rate for the motion type. As the user or vehicle moves, the system 100 determines which maximum change rate is reached first (i.e., the maximum rate from the motion type or the maximum rate from a given music layer 120) and will cap the change rate based on that value. Thus, if the music layer 120 has a maximum volume change rate per second of 0.05 and the system 100 is implemented in a vehicle (or in a mobile device in a vehicle) with a maximum volume change rate per second of 0.2, then the system 100 will determine when the change rate in volume per second exceeds 0.05 and will cap the change rate in volume per second to 0.05 accordingly.

In this way, the system 100 adapts the reaction times for the music layer 120 or music layers 120 following a change in speed to account for the motion type as well as individual layer 120 characteristics in order to produce a more balanced and enjoyable musical experience for the user. It is to be appreciated that this aspect of the present disclosure is part of the creative process in designing the musical experience of the system 100 and thus it may be subject to a high degree of variation based on design factors. Thus, the thresholds above may be significantly different (i.e., higher or lower) in some implementations based on the design choices made in implementing the system 100. The present disclosure is therefore not limited to only the above non-limiting illustrate example and other threshold values from 0 to 1 are contemplated and expressly included herein. In some implementations, the system 100 may also include an “idle” playback configuration in which the system 100 plays one or more music layers 120 based on the subsets or samples 112, 114 or another source described herein when motion has not changed enough to exceed a selected threshold. For example, if the system 100 detects zero acceleration or near zero acceleration (as defined herein), then the acceleration or other motion values may not exceed the selected or determined thresholds for initiation of music playback or a change in the music playback. Instead, in this idle playback configuration, the system 100 will begin audio playback until the motion exceeds the selected or determined thresholds according to the processes described herein.

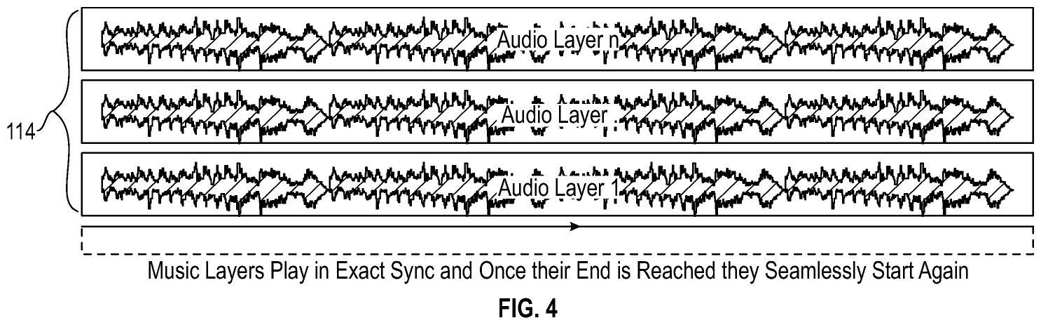

The system 100 can orchestrate playback of more than one audio sample, or more than one audio layer and each of these samples' playback properties can be configured independently as shown in FIGS. 4 and 5. For example, in FIG. 4, the audio layer 120 may be one of a second subset of audio samples 114 of the audio with the same length. As shown in FIG. 4, each of the layers or samples 114 have the exact same length, in one or more implementations. But in other implementations the lengths of the layers do not need to be identical. The system 100 can orchestrate playback of one or more, or all, of the layers or samples 114 at the same time, with different playback characteristics for each layer or sample 114. In one or more implementations, the system 100 uses the layers or samples 114 as loops, such that the layers or samples 114 play continuously until stopped by the system 100 or the user. In some implementations, each sample or layer 114 may further include playback of one or more of the first subset 112 of the audio files 102.

In some implementations, the resulting playback may be intended to be of a musical nature. In such implementations, it is preferred that these audio samples 112, 114 share the same musical key and tempo. The tempo information can then be used as a marker for the acceleration- or rotation-triggered audio samples described above, such that the acceleration-triggered audio samples will be in musical sync with the layers or samples 124 to create a musically cohesive and pleasant listening experience. Further, other marker points or markers in the layers or samples 114 can be defined and stored for future reference by the system 100. The markers provide pre-defined reference points at which to play the acceleration triggered events or where to begin playback when the system 100 orchestrates playback of the layers or samples 114 (e.g., when the system 100 changes the sample to be played and then returns to the original sample).

The first and second set of processor-executable instructions 104, 108 also allow for configuration of a number of different values or system 100 characteristics with respect to the playback of the second subset 114 of audio files. For example, the configurable values may include: number of audio layers; factor, formula, and processor-executable instructions regarding how vehicle speed or rotation affects playback properties or characteristics; value that determines how fast speed affects a given property; number of markers (if any) to define positions to return to or where to play acceleration-triggered audio samples; acceleration threshold related to jump to swap out set of audio samples (e.g., jump to another so-called acceleration level); and crossfade time when such an event occurs.

The second set of processor-executable instructions 108 are further configured to simultaneously orchestrate playback of audio samples from the first subset 112 of audio files 102 and the second subset 114 of audio files 102. By simultaneously playing audio samples that are flexible in their time of occurrence (first subset 112), and audio samples that have an independent time of occurrence (second subset 114), jagged and unpleasant changes in the overall audio experience can be avoided. For example, FIG. 5 represents how the combination of longer audio samples that react to speed and shorter audio samples that are triggered by acceleration events can create a dynamic, but cohesive audio composition. In FIG. 5, the system 100 and the second set of processor-executable instructions 108 orchestrate continuous playback of one or more of the second subset 114 of audio files 102 over time (indicated by line 126). The changing opacity of the second subset 114 of audio files 102 indicates a change in a playback property or characteristic, such as volume, panning, frequency filtering, among others, according to vehicle speed. Over time 126, acceleration or vehicle rotation triggers playback of one or more of the first subset 112 of audio files 102 occur. Because the first subset 112 of audio files 102 are typically shorter in duration, they can be rhythmically integrated into the longer second 114 of audio files 102 to create a cohesive, but dynamically changing musical experience for the user.

In some implementations, each of the second subset 114 of audio files 102 are the same length. For example, in FIG. 5, the second subset 114 of audio files includes a plurality of individual audio files 125A, 125B, which, when played back by the system 100 may be referred to herein as audio layers 125A, 125B. The plurality of individual audio files 125A, 125B include a first group of audio files 125A and a second group of audio files 125B. As described above, the system 100 can orchestrate playback of the first group of audio files 125A in the second subset 114 simultaneously and repeatedly as different audio layers each having the same or different playback properties and the same length. The second group of audio files 126B have a different and shorter length than the first group 125B of audio files in the second subset 114, as shown by break lines 127.

In some implementations, the second group of audio files 125B have a length that is a division of the longest audio file in the second subset 114 by a multiple of two. In one non-limiting example, the first group of audio files 125A have the longest length and the length of the second group of audio files 125B may be ½ or 1/16 of the length of the first group of audio files 125A. Further, playback of the first and second group of audio files 125A, 125B may be repeated. Because the second group of audio files 125B have a length that is a division by a multiple of two of the first group of audio files 125A, when the second group of audio files 125B are played simultaneously with the first group of audio files 125A (i.e., as different audio layers), the two groups 125A, 125B will terminate at the same time when the longest layer terminates and re-start in sync with each other.

However, it is not required for the second group of files 125B to have a length that is a division of the first group of audio files 125A by a multiple of two. In one or more implementations, the length of the second group of audio files 125B is ¾ of the length of the first group of audio files 125A or another selected length. In such implementations, the two groups of audio files 125A, 125B will still be in sync after a certain number of repetitions, such as three repetitions of the first group of audio files 125A and four repetitions of the second group of audio files 125B in the non-limiting illustrative example above. The system 100 can coordinate the transition between the two groups of audio files 125A, 125B when they are not in sync by changing the playback properties of each file or layer 125A, 125B. Using the same example above, when the system 100 determines that one of the files in the first group of audio files 125A is finished but the second group of audio files 125B will not be in sync with the first group 125A, the system 100 may alter playback properties of either or both groups 125A, 125B to create a smooth musical transition for the user.

In the above illustrative example, the second group of audio files 125B is one single audio file that is repeated during playback of the first group of audio files 125A. In some implementations, the second group of audio files 125B of the second subset 114 may be different, alternative audio files of the same or different length such that the system 100 can switch between alternative audio files in the second group of files 125B to change or refresh the musical experience over time. More specifically, the system 100 may switch between the different files in the second group of audio files 125B at a selected point in time during playback, such as when the system 100 determines that the volume of the second group of audio files 125B is reduced to zero. When the vehicle changes speed so that 125B's volume will increase, the system 100 will have selected a different audio file from the second group of audio files 125B to refresh the musical experience.

In one non-limiting example, when the system 100 has been playing the second subset 114 of audio files 102 for a selected period of time (such as 1 minute, 5 minutes, 10 minutes, 15 minutes, 20 minutes, 25 minutes, or 30 or more minutes) using the same audio file from the second group of audio files 125B, the system 100 will transition to a different or alternative audio file from the second group of audio files 125B at the next point in time when the system 100 determines that the volume of 125B is reduced to zero. Thus, when the vehicle speed later changes so that the volume of 125B will increase, the musical experience will change based on the change in the audio file selected from the available alternatives in the second group of audio files 125B. In some implementations, the first group of audio files 125A in the second subset 114 includes the same or different alternative audio files and the system 100 will select different alternatives over time in a similar manner to allow for further customization of the musical experience.

In some implementations, the system 100 also includes frequency filters that can be applied to the music layers (such as the first and second groups of audio files 125A, 125B in the second subset 114) based on the speed of the vehicle. For example, the system 100 may include low-pass filters, mid-pass filters, and high-pass filters that reduce or eliminate high frequencies, middle frequencies, and low frequencies from the music playback, respectively. The system 100 may include selected or adaptable speed thresholds that trigger application of one or more filters. In one non-limiting example, if the system 100 determines the vehicle's velocity is less than 30 kilometers per hour, the system 100 may apply a low pass filter to eliminate high frequencies from the playback of the layers, such as the first and second group of audio files 125A, 125B in FIG. 5. When the vehicle's velocity exceeds the selected 30 kilometer per hour threshold, the system 100 may apply a high pass filter to reduce or eliminate low frequencies and create a more exciting musical experience. Further, the system 100 may apply such filters to individual layers or all of the layers being played at a certain point in time. The velocity thresholds for application of the filters may be adaptable in any manner described herein, such as by referencing historical velocity data and selecting a different threshold for application of filters that is specific to a driver's driving style, among other possibilities.

The system 100 may also include an audio delay or echo effect that assists with the combination of separate music layers or the repetition of layers during the audio playback. The timing of the audio delay can be selected based on the tempo of the music files that are currently being played by the system 100. The audio delay effect records an input signal to a storage medium of the system 100 and plays the recorded signal back one or more times after a selected period of time to create a repeating, decaying echo effect. This echo effect assists with the transition or combination of musical elements because it avoids abrupt endings or abrupt transitions between the audio files that disrupt the musical experience. Instead, with the audio delay effect, audio files are gradually introduced and faded out in a continuous manner. Both the audio filters and the audio delay or echo effect, along with other concepts of the disclosure, may be implanted using a real-time development platform in one non-limiting example, although other programming platforms, methods, and languages are contemplated herein.

The system 100 further organizes the audio files 102 into different content packages or groupings. The first grouping is called acceleration levels. Acceleration levels are a set of acceleration triggered audio samples 112, and audio samples with speed dependent characteristics 114, together with fitting configurations of parameters. The system 100 can jump from one acceleration level to another one, triggered by very high acceleration events or other user input. In other words, the content in each acceleration level corresponds to a certain magnitude of acceleration determined by the system 100 from the motion data 106. For example, in a low acceleration level, the content may include more peaceful audio content at lower volume. In a high acceleration level, the audio content may be higher tempo and more exciting and played at a higher volume. When very high acceleration is detected or identified, the system 100 switches between acceleration levels accordingly.

The second content grouping is called an audio pool. An audio pool is a set of acceleration levels. In some implementations, the audio pools define minimum and maximum thresholds of velocity and acceleration as well as minimum time passed since the last jump to another acceleration level. For example, if there is an audio pool with a slow and a fast acceleration level and the system 100 determines that an acceleration event warrants a jump to the fast audio level, the system 100 will not return to the slow audio level (e.g., will remain at the lower one of the two acceleration levels) until a certain event occurs, such as a rapid deceleration or a certain period of time.

The third content grouping is called a style and in other implementations can be called playlist or experience. A style is a set of audio pools. This is the highest level of content organization, in one or more implementations. A style is a creative (or musical) direction with a corresponding set of pools, which contain acceleration levels, that are all part of one cohesive experience (e.g., a “jungle” style could contain audio samples of birds, crickets, monkeys, human drumming, organized into the above-mentioned structure and a “Hollywood soundtrack” style could contain only musical elements, such as foreboding atmospheric elements, strings melodies and fast paced action drumming, all organized into above mentioned structure). Further, each of the acceleration levels, audio pools, and styles can be referred to by a different name, such as first, second, and third content levels, sub-levels, structures, or other names.

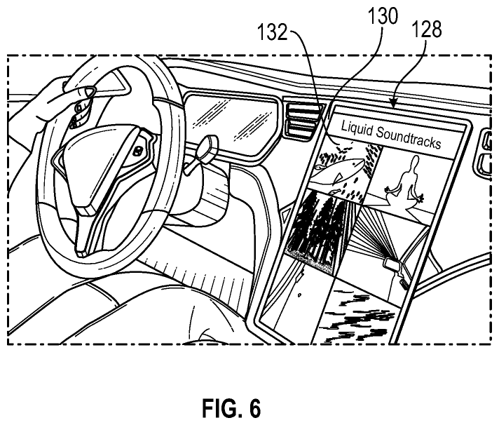

FIG. 6 is a picture of an example user interface 128 in a touch screen control system 130 of a vehicle. The user interface 128 may include a number of different style-grouping selections for the user, each represented by a different icon 132. When the user selects a certain icon 132, the system 100 will operate with the audio files 102 assigned to that style in order to orchestrate playback of the audio files 102 within that style. The user interface 128 may include additional options after selecting the style icon 132, such as, random or sequential playback of audio files 132 within organizational levels, or other features and characteristics described herein.

The system 100 further includes a set of parameters that are configured for each creative approach. For example, a certain creative approach or a style may include configurable parameters specific to that approach, such as: acceleration thresholds for regular acceleration and deceleration; acceleration thresholds for high acceleration and deceleration; fade in and fade out time when changing acceleration levels; a smoothing value, which determines how fast or slow continuous property changes should follow input signals; and a cool down time that determines how long the system should wait after triggering an acceleration-dependent event, before allowing a new acceleration-dependent to be triggered.

The described system 100 will create motion adaptive audio experiences, independent of the device and hardware it is running on, or the programming language that is used to execute the described functionality. In one or more implementations, the system 100 has been programmed in C # and uses the game engine Unity®. It can be executed on an Android® mobile phone, using motion information from the phone's Accelerometer and GPS data. The system 100 can include filtering, cleaning up and combining GPS and accelerometer data to calculate reliable speed and acceleration data.

As mentioned above, this system can also run on a car's own operating system and receive clean and reliable acceleration and speed data directly from a car's operating system, in which case the above-mentioned step of filtering input signals may not be necessary.

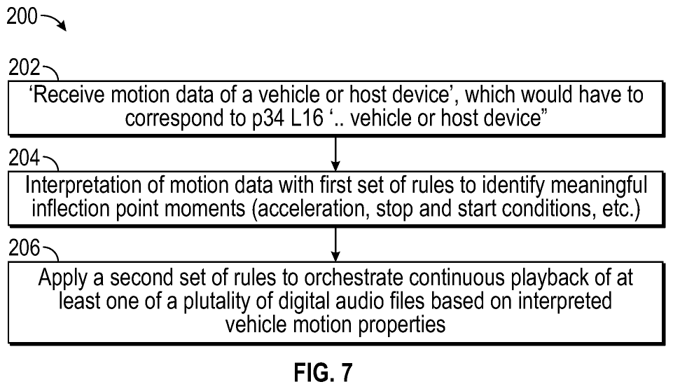

FIG. 7 is a logic flow diagram of a method 200 for orchestrating continuous playback of one or more audio samples based on motion data of a vehicle or host device. The method 200 begins at 202 by a system, such as system 100, receiving or obtaining motion data of a vehicle. The motion data may be vehicle acceleration data, vehicle speed data, or both, as well as other motion data instead of or in addition to the acceleration and speed data. The vehicle motion data at 202 may be received from the vehicle's on-board computer system and may include data generated from GPS, or may be received from a user's mobile phone and associated systems, among other sources described herein. The system may smooth the vehicle acceleration and speed data using averages, as explained above. Then, the method continues at 204 with interpretation of the motion data obtained at 202. The interpretation of the motion data at 204 includes determining inflection point moments, which may include acceleration inflection point moments, speed inflection point moments, or both. Further, the interpretation may include determining change in direction inflection point moments (e.g., the vehicle changing direction from a left or right turn, etc.) as well as inflection point moments associated with directional acceleration and directional speed (e.g. left or right acceleration, etc.). The interpretation at 204 may further include identifying stop and start conditions of the vehicle, in one or more implementations.

Once the system has identified the meaningful inflection point moments at 204, the method 200 continues by orchestrating playback of digital audio files at 206. Orchestrating playback of the audio files includes continuously playing longer digital audio files and altering playback characteristics of the longer digital audio files in response to one or more of the acceleration inflection point moments, the speed inflection point moments, or both. Altering the playback characteristics may include altering tone, intensity, volume, bass, treble, fade, and other like characteristics of the longer audio files. Further, orchestrating playback includes inserting and arranging one or more shorter audio files into the continuous playback of the longer audio files in response to one or more acceleration inflection point moments or events, one or more speed inflection point moments or events, or both.

The shorter audio files may not be played, may not have their playback parameters changed, or both, in some implementations. However, the longer audio files are usually played and may have their playback parameters changed, in one or more implementations. The method 200 then continues to cycle through 202, 204, and 206 based on changes in vehicle motion data or characteristics. In other words, method 200 is an on-going process that continues from when the user activates the system and begins operating the vehicle to when the user deactivates the system. As such, further vehicle motion data is gathered while the user is driving, which causes the method to restart at 202 and continue as above. As such, the method 200 provides for a continuous playback of audio files based on vehicle motion characteristics, wherein the audio output adapts to the vehicle motion characteristics to provide a continuous and changing musical experience, similar to a movie soundtrack, but unique to the vehicle's motion. In one or more other implementations, an adaptive audio experience vehicle system may be summarized as including: at least one processor; and at least one nontransitory processor-readable medium that stores processor-executable instructions, wherein the at least one processor: obtain motion data of the vehicle, the motion data of the vehicle including vehicle acceleration data, vehicle speed data, or both; interpret the motion data of the vehicle to determine acceleration and speed values of the vehicle based on motion data of the vehicle; and orchestrate playback of a digital audio file, wherein the orchestrated playback includes correlating playback characteristics of the digital audio file to at least one of: acceleration values of the vehicle and speed values of the vehicle.

In some implementations, the interpreting of the motion data further includes identifying stop and start conditions of the vehicle. Additionally, the orchestrated playback further includes correlating playback characteristics of the digital audio file to include stop and start conditions of the vehicle. In another implementation, the playback characteristics of the digital audio file include tone, intensity, volume, bass, and treble. In still another implementation, determining acceleration and speed values of the vehicle includes: averaging the vehicle speed and acceleration data to filter out short-term oscillation of the vehicle. In yet another implementation, determining acceleration and speed values of the vehicle includes: averaging vehicle GPS signals to smooth the GPS signals. In another implementation, determining acceleration and speed values of the vehicle includes: adaptive smoothing and averaging of vehicle acceleration and speed data based on absolute speed. In still another implementation, determining acceleration and speed values of the vehicle includes: distilling motion direction of the vehicle through a vector calculation by removing gravitational forces from the vector calculation. In other implementations, the orchestrating playback of the digital audio file includes: allocating a plurality of first subsets of the plurality of digital audio files to each of a plurality of acceleration directions. In another implementation, orchestrating playback of the digital audio file includes: determining an instance of vehicle acceleration and a vehicle acceleration direction at the instance of vehicle acceleration. In still another implementation, orchestrating playback of the digital audio file includes: selecting, based on the vehicle acceleration direction or rotation direction, a playback characteristic of the digital audio file corresponding to the vehicle acceleration direction or rotation direction. In another implementation, the system may further comprise: selecting a second, third or more digital audio files based on vehicle speed. In yet another implementation, the system may further comprise: continuously adjusting a playback property of the second digital audio file based on vehicle speed. In another implementation, the system may further comprise: simultaneously orchestrating playback of a first digital audio file that is flexible in time of occurrence and a second digital audio file that is independent time of occurrence.

In one or more implementations, an adaptive audio experience vehicle system may be summarized as including: at least one processor; and at least one nontransitory processor-readable medium that stores processor-executable instructions, wherein the at least one processor: access motion data of the vehicle, the motion data of the vehicle including vehicle acceleration data, vehicle speed data, or both; examine the motion data of the vehicle to determine acceleration and speed values of the vehicle based on motion data of the vehicle; and organize playback of one or more digital audio files, wherein the organized playback includes correlating playback characteristics of the one or more digital audio files to at least one of: acceleration values of the vehicle and speed values of the vehicle.

In the foregoing description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with vehicle acceleration, speed and direction collection (such as speedometers, GPS receivers or transceivers, accelerometers, compass and other like devices) and audio systems (such as speakers, transducers, amplifiers, and other like devices) have not been shown or described in detail to avoid unnecessarily obscuring descriptions of the implementations.

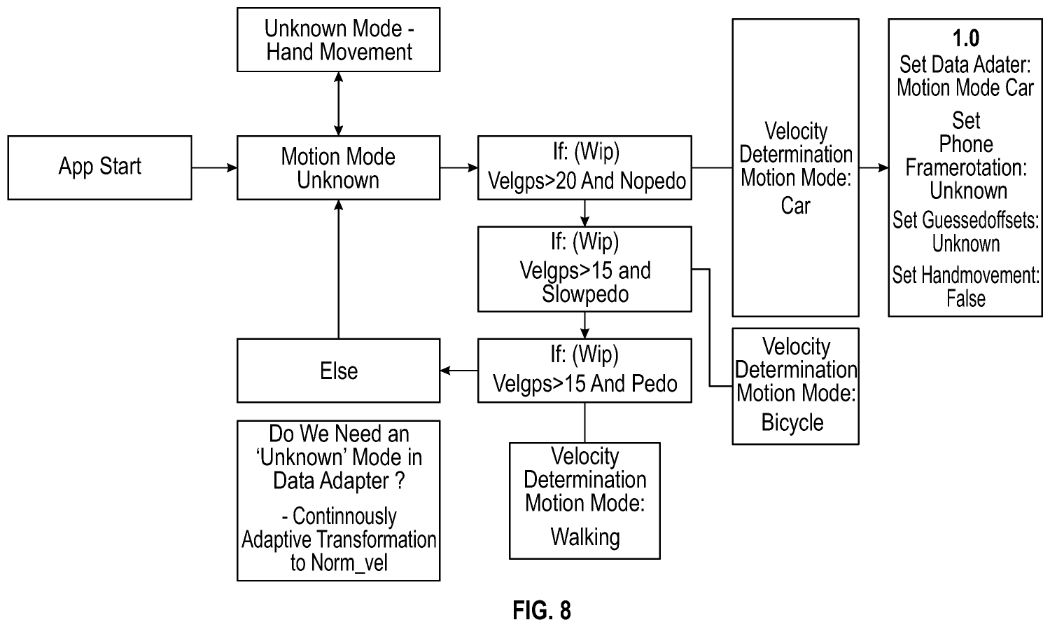

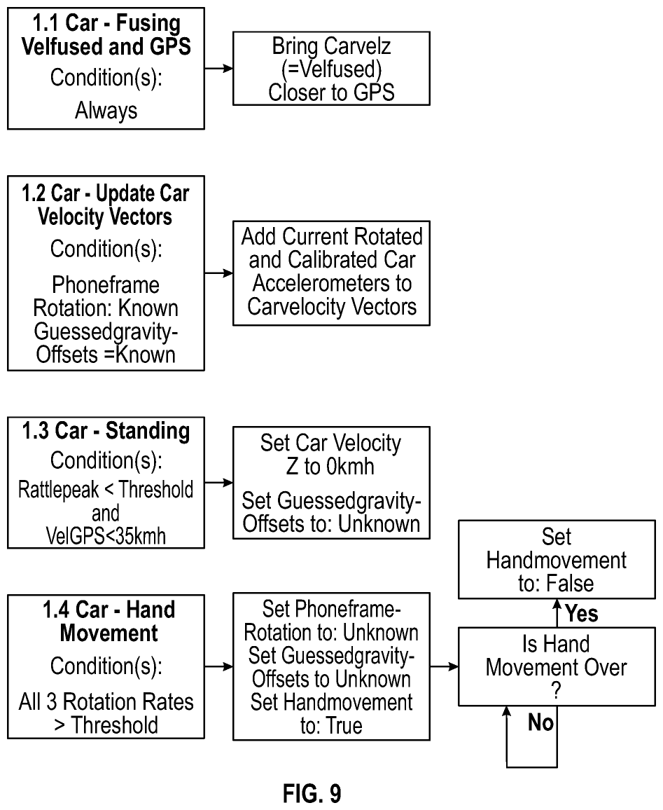

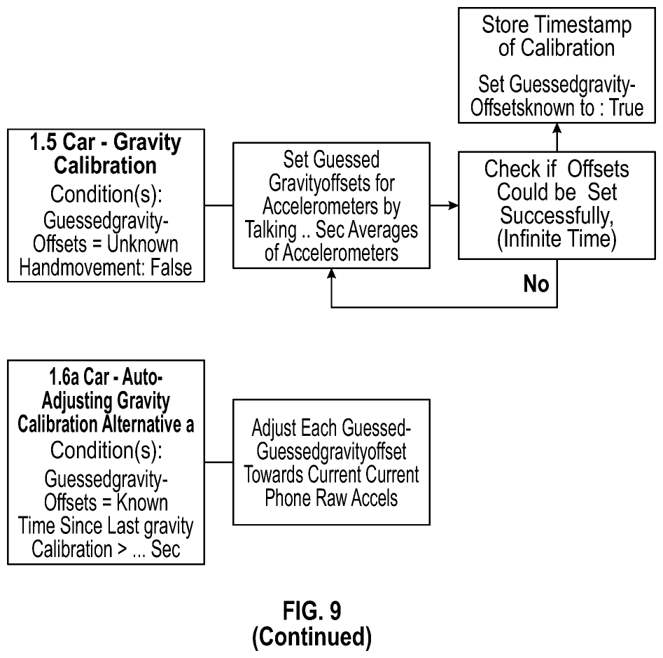

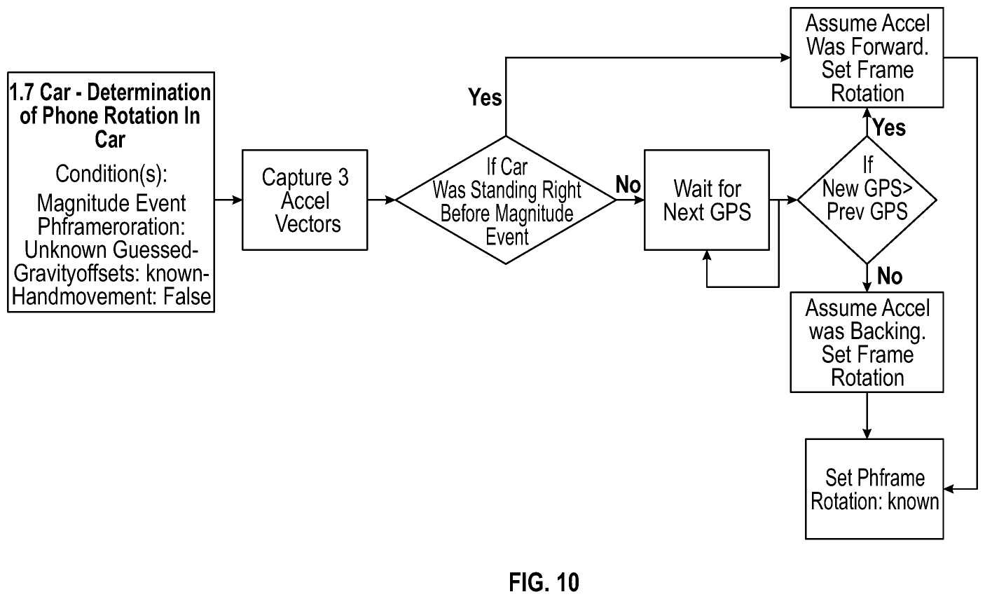

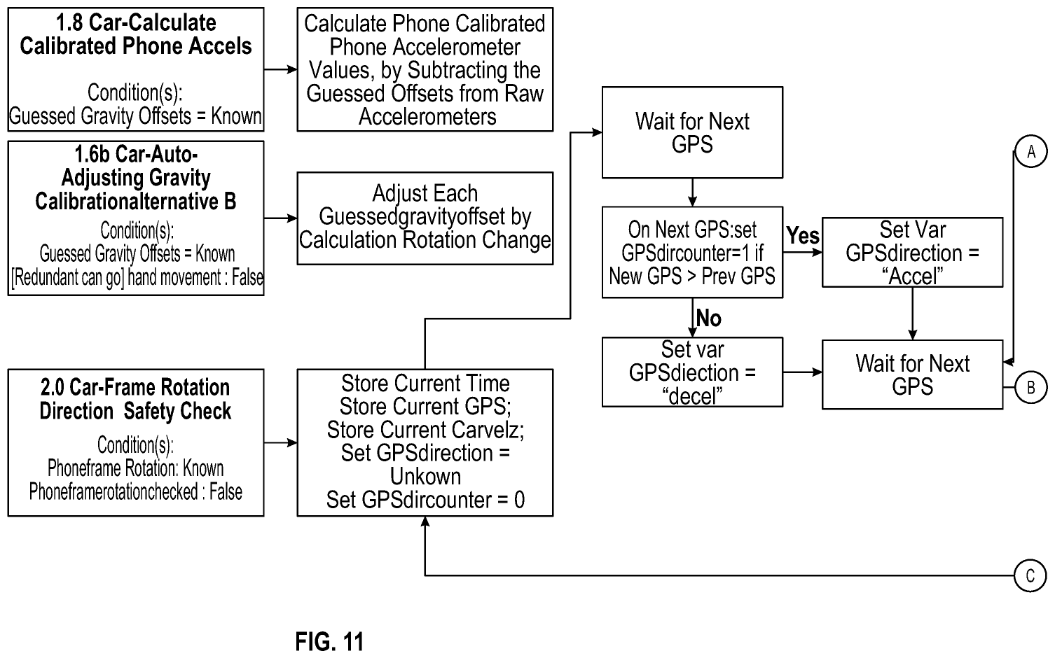

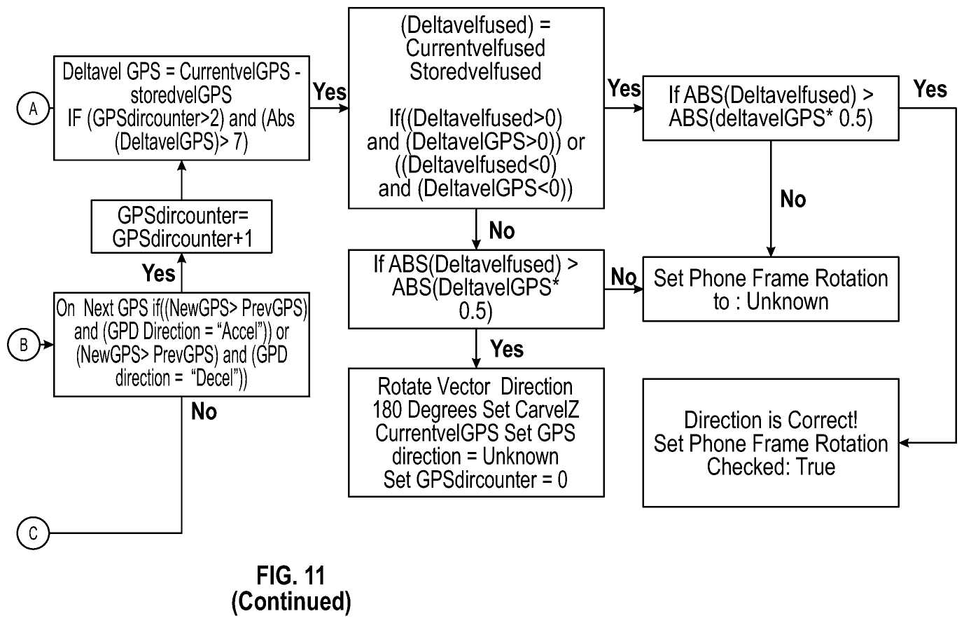

Referring now to FIGS. 8-11, logic diagrams are shown that include functions and calculations in the motion and velocity determination process, in one or more implementations of the motion adaptive audio experience system. In the velocity determination motion mode, the logic components include 1.1 Fuse Velocity And GPS Velocity, 1.2 Updated Car Velocity Vectors By Adding Rotated and Calibrated Accelerometers, 1.3 Velocity To 0 And Set Gravity Offsets To Unknown, 1.4 Toss Calibrations Due To Hand Movement, 1.5 Calibrate Accelerometers To Subtract Gravitation, 1.6 Ongoing Auto-Adjusting Of Gravity Calibration By Car Rotation Or Offset Reduction Via Averages, 1.7 Determination Of Phone Rotation In Car When First Acceleration Occurs, 1.8 Calculate Calibrated Phone Acceleration, and 2.0 Frame Rotation Direction Safety Check.

Unless the context requires otherwise, throughout the specification and claims which follow, the word “comprise” and variations thereof, such as, “comprises” and “comprising” are to be construed in an open, inclusive sense, that is as “including, but not limited to.” Further, the terms “first,” “second,” and similar indicators of sequence are to be construed as interchangeable unless the context clearly dictates otherwise.

Reference throughout this specification to “one implementation” or “an implementation” means that a particular feature, structure or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

The relative terms “approximately” and “substantially,” when used to describe a value, amount, quantity, or dimension, generally refer to a value, amount, quantity, or dimension that is within plus or minus 5% of the stated value, amount, quantity, or dimension, unless the content clearly dictates otherwise. It is to be further understood that any specific dimensions of components provided herein are for illustrative purposes only with reference to the implementations described herein, and as such, the present disclosure includes amounts that are more or less than the dimensions stated, unless the context clearly dictates otherwise.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied outside of the motion adaptive audio and vehicle context, and not necessarily the exemplary motion adaptive audio systems, methods, and devices generally described above.

For example, the motion adaptive audio systems described herein can be used with other devices with a speaker system, such as on a boat, in a mobile electronic device (smart phone, smart device, mobile speaker, tablet, and other like devices), wireless headphones, or any other mobile system with connected, either wired or wirelessly, speakers for audio playback. While the illustrated implementations include a motion adaptive audio system for a vehicle, it is to be appreciated that modifications within the scope of this disclosure include the motion adaptive audio system adapted for used for any other mobile device or system with audio playback capabilities. As such, other applications and adaptations are contemplated and expressly included herein.

The foregoing detailed description has set forth various implementations of the devices and processes via the use of certain implementations. Insofar as such implementations contain one or more functions and operations, it will be understood by those skilled in the art that each function and operation within such implementation can be implemented, individually or collectively, by a wide range of hardware, software, firmware, or virtually any combination thereof. In one implementation, the present subject matter may be implemented via Application Specific Integrated Circuits (ASICs). However, those skilled in the art will recognize that the implementations disclosed herein, in whole or in part, can be equivalently implemented in standard integrated circuits, as one or more computer programs executed by one or more computers (e.g., as one or more programs running on one or more computer systems), as one or more programs executed by on one or more controllers (e.g., microcontrollers) as one or more programs executed by one or more processors (e.g., microprocessors), as firmware, or as virtually any combination thereof.

When logic is implemented as software and stored in memory, logic or information can be stored on any computer-readable medium for use by or in connection with any processor-related system or method. In the context of this disclosure, a memory is a computer-readable medium that is an electronic, magnetic, optical, or other physical device or means that contains or stores a computer and/or processor program. Logic and/or the information can be embodied in any computer-readable medium for use by or in connection with an instruction execution system, apparatus, or device, such as a computer-based system, processor-containing system, or other system that can fetch the instructions from the instruction execution system, apparatus, or device and execute the instructions associated with logic and/or information.

In the context of this specification, a “computer-readable medium” can be any element that can store the program associated with logic and/or information for use by or in connection with the instruction execution system, apparatus, and/or device. The computer-readable medium can be, for example, but is not limited to, an electronic, magnetic, optical, electromagnetic, infrared, or semiconductor system, apparatus or device. More specific examples (a non-exhaustive list) of the computer readable medium would include the following: a portable computer diskette (magnetic, compact flash card, secure digital, or the like), a random access memory (RAM), a read-only memory (ROM), an erasable programmable read-only memory (EPROM, EEPROM, or Flash memory), a portable compact disc read-only memory (CDROM), digital tape, and other nontransitory media.

Many of the methods described herein can be performed with variations. For example, many of the methods may include additional acts, omit some acts, and perform acts in a different order than as illustrated or described.

The various implementations described above can be combined to provide further implementations. To the extent that they are not inconsistent with the specific teachings and definitions herein, all of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the implementations can be modified, if necessary to employ concepts of the various patents, applications and publications to provide yet further implementations.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A method of adaptive audio experience in a vehicle, comprising:
obtaining motion data of the vehicle, the motion data of the vehicle including one or more of vehicle acceleration data, vehicle speed data, vehicle heading data, or vehicle rotation speed data;
interpreting the motion data of the vehicle to determine inflection point acceleration events, inflection point speed events and inflection point rotation events of the vehicle; and
orchestrating playback of digital audio files, wherein the orchestrating of playback includes making two types of changes to the playback of the digital audio files, the first type of change including one or more of inserting and arranging shorter audio files into a playback in response to one or more of inflection point acceleration events and inflection point speed events, the second type of change including altering playback characteristics of longer digital audio files in response to one or more of inflection point acceleration events and inflection point speed events.

2. The method of claim 1, wherein the interpreting of the motion data further includes identifying stop and start inflection point moments corresponding to stop and start conditions of the vehicle, and wherein the orchestrating playback further includes correlating the playback characteristics of the longer digital audio files in response to the stop and start inflection point moments.

3. The method of claim 1, wherein the altering the playback characteristics of the longer digital audio files includes altering one or more of tone, intensity, volume, bass, fade-time, highpass filter, lowpass filters and treble of the longer digital audio files.

4. The method of claim 1, wherein the interpreting the motion data of the vehicle includes: averaging the vehicle speed and vehicle acceleration data to filter out short-term oscillation of the vehicle.

5. The method of claim 1, wherein the calculation the motion data of the vehicle includes: averaging vehicle GPS signals to smooth the GPS signals.

6. The method of claim 1, wherein the interpreting the motion data of the vehicle includes: adaptive smoothing and averaging of vehicle acceleration and speed data based on absolute speed.

7. The method of claim 1, wherein the interpreting the motion data of the vehicle includes: distilling motion direction of the vehicle through a vector calculation by removing gravitational forces from the vector calculation.

8. The method of claim 1, wherein the interpreting the motion data of the vehicle includes: determining an instance of vehicle acceleration and a vehicle acceleration direction at the instance of vehicle acceleration.

9. The method of claim 1, further comprising: simultaneously orchestrating playback of a first digital audio file of the plurality of digital audio files that is flexible in time of occurrence and a second digital audio file of the plurality of digital audio files that is independent in time of occurrence.

10. An adaptive audio experience vehicle system, comprising:
at least one processor; and
at least one nontransitory processor-readable medium that stores processor-executable instructions, wherein the at least one processor:
obtains motion data of the vehicle, the motion data of the vehicle including vehicle acceleration data, vehicle speed data, or both;
interprets the motion data of the vehicle or host device to determine acceleration, speed and rotation events of the vehicle based on motion data of the vehicle; and
orchestrates playback of a digital audio file, wherein the orchestrated playback includes correlating playback characteristics of the digital audio file to at least one of: acceleration values of the vehicle, speed values of the vehicle and rotation values of the vehicle.

11. The system of claim 10, wherein orchestrating playback of the digital audio file includes: allocating a plurality of first subsets of a plurality of digital audio files to each of a plurality of acceleration directions.

12. The system of claim 10, wherein orchestrating playback of the digital audio file includes: determining an instance of vehicle acceleration and a vehicle acceleration direction at the instance of vehicle acceleration or an instance of vehicle rotation and a rotation direction at the instance of vehicle rotation.

13. The system of claim 12, wherein orchestrating playback of the digital audio file includes: altering, based on the vehicle acceleration direction, a playback characteristic of the digital audio file based on the vehicle acceleration direction.

14. The system of claim 10, further comprising: selecting a second digital audio file based on vehicle speed.

15. The system of claim 10, further comprising: continuously adjusting a playback property of the second digital audio file based on vehicle speed.

16. A method of adaptive audio experience in a mobile device, comprising:
interpreting motion data of the mobile device to determine inflection point acceleration events and inflection point speed events of the mobile device; and
orchestrating playback of digital audio files, wherein the orchestrating of playback includes making two types of changes to the playback of the digital audio files, the first type of change including one or more of inserting and arranging shorter audio files into a playback in response to one or more of inflection point acceleration events and inflection point speed events, the second type of change including altering playback characteristics of longer digital audio files in response to one or more of inflection point acceleration events and inflection point speed events.

17. The method of claim 16 wherein interpreting the motion data of the mobile device includes adjusting inflection point acceleration event thresholds based on speed of the mobile device.

18. The method of claim 16 wherein interpreting the motion data of mobile device includes adjusting inflection point acceleration event thresholds over time based on changes in speed or acceleration, or both, over time.

19. The method of claim 16 wherein orchestrating playback of the digital audio files includes limiting a rate of change of the playback characteristics based on a motion type of the mobile device.

20. The method of claim 16 wherein orchestrating playback of the digital audio files includes, in the second type of change, simultaneously playing two different groups of longer audio files, a length of the first group being greater than a length of the second group, the method further comprising:
selecting a different longer audio file from the second group of longer audio file over time.
